(19) United States
(12) Patent Application Publication
(10) Pub. No.: US 2009/0262795 A1
(43) Pub. Date: Oct. 22, 2009

(54) Adaptive equalizer tap stepsize

(76) Inventor: Aaron Reel Bouillet, Nobelsville, IN (US)

Correspondence Address: Thomson Licensing LLC, P.O. Box 5312, Two Independence Way, PRINCETON, NJ, 08543-5312, US

(21) Appl. No.: 11/988,898

(22) PCT Filed: Sep. 26, 2005
(86) PCT No.: PCT/US2005/034713

§ 371 Date: Jan. 16, 2008

Related U.S. Application Data
(60) Provisional application No. 60/700,630, filed on Jul. 19, 2005.

(51) Int. Cl. H03K 5/159

(52) U.S. Cl. 375/232

(57) ABSTRACT

An apparatus comprises an adaptive filter having groups of taps, each group comprising at least one tap having an associated tap value; and a controller for selecting a scaling factor for at least one group of taps as a function of tap values of the group. The controller further adjusts an error value as a function of the selected scaling factor. The adaptive filter adapts tap values of the at least one group of taps as a function of the adjusted error value.

### CROSS-REFERENCE TO RELATED APPLICATIONS

This application claims the benefit of U.S. Provisional Application No. 60/700,630, filed Jul. 19, 2005.

### BACKGROUND OF THE INVENTION

The present invention generally relates to communications systems and, more particularly, to adaptive filters, which, e.g., are used to form filter elements such as an equalizer.

Many digital data communication systems employ adaptive equalization to compensate for the effects of changing channel conditions and disturbances on the signal transmission channel. The ability of an equalizer to adaptively acquire and track time varying channels is a function of how much gain is applied to the tap update process. More gain results in an ability to handle more rapidly varying channel conditions, but only up to a point. Once that point is exceeded, the gain causes excessive jitter in the taps which degrades the fidelity of the equalizer output.

One method of controlling this self-induced tap noise under high gain control is to implement a bias on the taps that drives them to zero when the only other driving force on them is random in nature. The disadvantage of this approach is that as the gain continues to increase, the value of the bias toward zero must also increase, i.e., become stronger. This results in the bias value effectively limiting the amount of gain that can be applied.

### SUMMARY OF THE INVENTION

I have observed that it is possible to apply high gain to an equalizer—independent of any bias value (if present)—and still prevent the generation of excess noise. Thus, further improving the ability of an equalizer to quickly adapt to changing conditions. In particular, and in accordance with the principles of the invention, an apparatus comprises an adaptive filter having groups of taps, each group comprising at least one tap having an associated tap value; and a controller for selecting a scaling factor for at least one group of taps as a function of tap values of the group and for adjusting an error value as a function of the selected scaling factor; wherein the adaptive filter adapts tap values of the at least one group of taps as a function of the adjusted error value. As a result, it is possible to apply high gain to only those taps of the filter that are adaptively found to have significant influence on the filter response, thereby obtaining the benefit of high gain on taps where it is needed while preventing the generation of excess noise.

In accordance with an embodiment of the invention, a receiver comprises an equalizer, the equalizer having groups of taps, each group comprising at least one tap having an associated tap value; and wherein the equalizer adjusts tap values in each group, wherein the tap values of at least one group are adjusted as a function of a stepsize, the value of which is selected as a function of tap values of the group.

### BRIEF DESCRIPTION OF THE DRAWINGS

Preferred embodiments of the present invention will be described below in more detail, with reference to the accompanying drawings.

FIG. 1 illustrates a prior art decision feedback equalizer;

FIG. 2 shows an illustrative block diagram of a receiver in accordance with the principles of the invention;

FIG. 3 shows an illustrative decision feedback equalizer in accordance with the principles of the invention;

FIG. 4 further illustrates the inventive concept in the context of the decision feedback equalizer of FIG. 3;

FIG. 5 is an illustrative flow chart illustrating a method in accordance with the principles of the invention;

FIG. 6 shows illustrative thresholds for use in the flow chart of FIG. 5; and

FIG. 7 shows another illustrative embodiment in accordance with the principles of the invention.

### DETAILED DESCRIPTION

Other than the inventive concept, the elements shown in the figures are well known and will not be described in detail. Also, familiarity with television broadcasting and receivers is assumed and is not described in detail herein. For example, other than the inventive concept, familiarity with current and proposed recommendations for TV standards such as NTSC (National Television Systems Committee), PAL (Phase Alternation Lines), SECAM (SEquential Couleur Avec Memoire) and ATSC (Advanced Television Systems Committee) (ATSC) is assumed. Likewise, other than the inventive concept, transmission concepts such as eight-level vestigial sideband (8-VSB), Quadrature Amplitude Modulation (QAM), and receiver components such as a radio-frequency (RF) front-end, or receiver section, such as a low noise block, tuners, and demodulators is assumed. Similarly, formatting and encoding methods (such as Moving Picture Expert Group (MPEG)-2 Systems Standard (ISO/IEC 13818-1)) for generating transport bit streams are well-known and not described herein. It should be noted that the inventive concept may be implemented using conventional programming techniques, which, as such, will not be described herein. Finally, like-numbers on the figures represent similar elements.

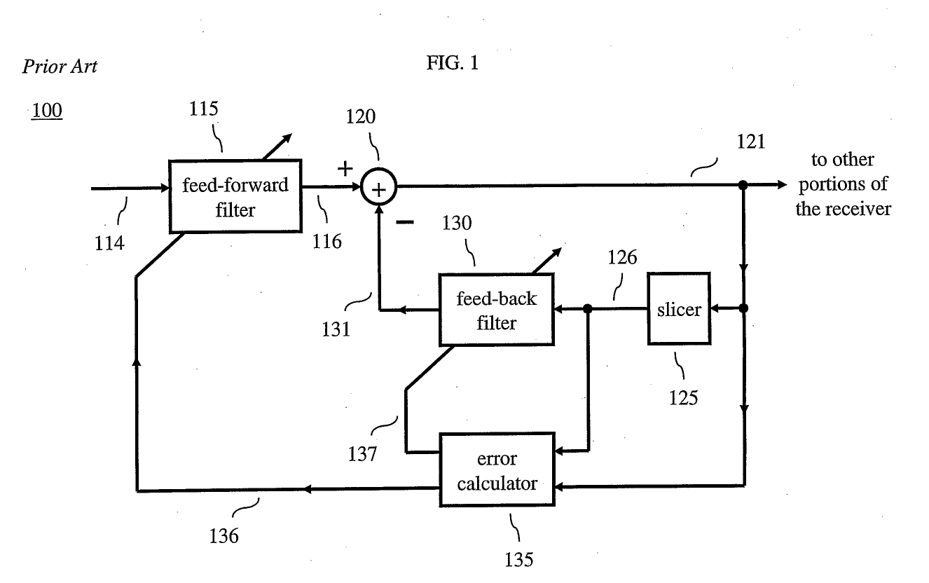

Turning now to FIG. 1, a prior art decision feedback equalizer (DFE) 100 is shown. DFE 100 comprises feed-forward (FF) filter 115, adder 120, slicer 125, feed-back (FB) filter 130 and error calculator 135. Both FF filter 115 and FB filter 130 are adaptive filters as known in the art, each filter comprising a number taps (also referred to in the art as coefficients) (not shown), each tap having a tap value (or coefficient value). In order to facilitate hardware efficiency, the taps of each filter are commonly arranged in groups that share an expensive resource such as a large multiplier. In terms of operation, unequalized data, via signal 114, enters FF filter 115, which provides FF output signal 116 to adder 120. The latter sums FF output signal 116 with FB output signal 131 from FB filter 130 to provide equalized output signal 121. The equalized output signal 121 is provided to other portions of the receiver (not shown) and to slicer 125. Equalized output signal 121 represents a sequence of signal points, each signal point have in-phase (I) and quadrature (Q) values in a constellation space. DFE 100 is a feedback device, the feedback path comprising slicer 125 and FB filter 130. Slicer 125 is a decision device as known in the art and makes “hard decisions” as to the possibly transmitted symbol from the equalized output signal. In particular, for each signal point of equalized output signal 121, slicer 125 compares the signal point to a symbol constellation (not shown) in the constellation space and selects that symbol of the symbol constellation that is closest to the value of the signal point. As a result, slicer 125 provides a sequence of symbols to FB filter 130 via signal 126. (Hence the terminology Decision Feedback Equalizer.) FB filter 130 filters this sequence of symbols and provides FB output signal 131 to adder 120 (as described earlier).

As noted above, both FF filter 115 and FB filter 130 are adaptive filters, i.e., the tap values are adjusted over time such that the overall filter response can adapt to changing channel conditions. The adjustment of the tap values for FF filter 115 and FB filter 130 are performed as a function of the amount of equalized data error (or simply “error”), which is determined by error calculator 135. The latter determines the error in any one of a number of ways, the most common being the Constant Modulus Algorithm (CMA), the Decision-Directed method, or by training. The training and CMA methods only need the equalized output signal (also referred to herein as the “soft equalizer output signal”) to derive an error, while the Decision-Directed method uses both the soft equalizer output signal and the hard decisions from a slicer to derive the error. As such, FIG. 1 shows error calculator 135 receiving both signals 121 and 126. Due to inherent gain differences in FF filter 115 and FB filter 130, the error is scaled differently for each filter. This is represented in FIG. 1 by the use of individual adjustment signals 136 and 137 for FF filter 115 and FB filter 135, respectively.

As noted earlier, the ability of an equalizer to adaptively acquire and track time varying channels is a function of how much gain is applied to the tap update process. Unfortunately, large gain values may require the use of a bias value in the tap update process to limit the amount of self-induced tap noise. In addition, this method of using a bias value to control self-induced tap noise further limits how much gain can be applied to the tap update process. However, I have observed that it is possible to apply high gain to an equalizer—independent of any bias value (if present)—and still prevent the generation of excess noise. Thus, further improving the ability of an equalizer to quickly adapt to changing conditions. In particular, and in accordance with the principles of the invention, an apparatus comprises an adaptive filter having groups of taps, each group comprising at least one tap having an associated tap (coefficient) value; and a controller for selecting a scaling factor for at least one group of taps as a function of tap values of the group and for adjusting an error value as a function of the selected scaling factor; wherein the adaptive filter adapts tap values of the at least one group of taps as a function of the adjusted error value. As a result, it is possible to apply high gain to only those taps of the filter that are adaptively found to have significant influence on the filter response, thereby obtaining the benefit of high gain on taps where it is needed while preventing the generation of excess noise.

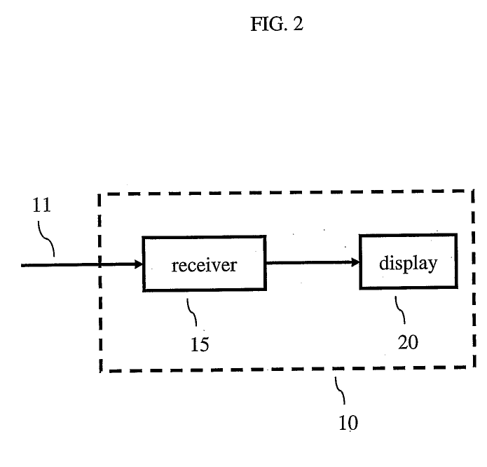

A high-level block diagram of an illustrative television set 10 in accordance with the principles of the invention is shown in FIG. 2. Television (TV) set 10 includes a receiver 15 and a display 20. Illustratively, receiver 15 is an ATSC-compatible receiver. It should be noted that receiver 15 may also be NTSC (National Television Systems Committee)-compatible, i.e., have an NTSC mode of operation and an ATSC mode of operation such that TV set 10 is capable of displaying video content from an NTSC broadcast or an ATSC broadcast. For simplicity in describing the inventive concept, only the ATSC mode of operation is described herein. Receiver 15 receives a broadcast signal 11 (e.g., via an antenna (not shown)) for processing to recover therefrom, e.g., an HDTV (high definition TV) video signal for application to display 20 for viewing video content thereon.

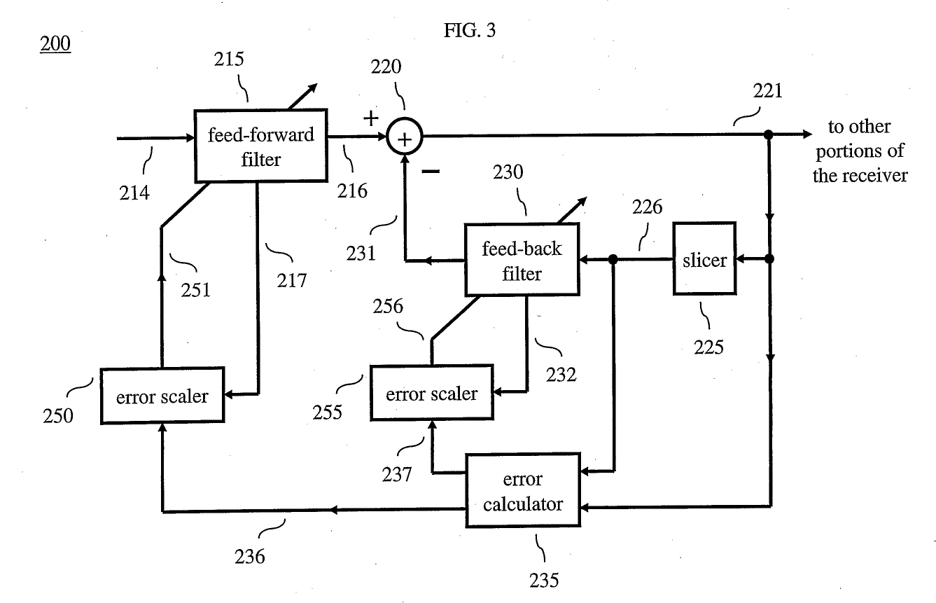

Referring now to FIG. 3, an illustrative embodiment of a decision feedback equalizer (DFE) 200 of receiver 15 in accordance with the principles of the invention is shown. DFE 200 comprises feed-forward (FF) filter 215, adder 220, slicer 225, feed-back (FB) filter 230, error calculator 235, error scaler 250 and error scaler 255. Both FF filter 215 and FB filter 230 are adaptive filters, each filter comprising a number taps (coefficients) (not shown), each tap having a tap value (or coefficient value). Other than the inventive concept, DFE 200 functions in a manner similar to that described above for DFE 100. In particular, unequalized data, via signal 214, enters FF filter 215, which provides FF output signal 216 to adder 220. The latter sums FF output signal 216 with FB output signal 231 from FB filter 230 to provide equalized output signal 221. The equalized output signal 221 is provided to other portions of the receiver (not shown) and to slicer 225. Equalized output signal 221 represents a sequence of signal points, each signal point have in-phase (I) and quadrature (Q) values in a constellation space. Slicer 225 makes “hard decisions” as to the possibly transmitted symbol from the equalized output signal and provides a sequence of symbols, 226, to FB filter 230. The latter filters this sequence of symbols and provides FB output signal 231 to adder 220.

As before, error calculator 235 determines the amount of equalized data error (error). As noted above, any one of a number of techniques may be used, the most common being the Constant Modulus Algorithm (CMA), the Decision-Directed method, or by training. The training and CMA methods only need the equalized output signal (also referred to herein as the “soft equalizer output signal”) to derive an error, while the Decision-Directed method uses both the soft equalizer output signal and the hard decisions from a slicer to derive the error. As such, FIG. 2 shows error calculator 235 receiving both signals 221 and 226, although only one of them may be required. The actual method for determining the equalized data error is irrelevant to the inventive concept. Since, as noted above, there may be inherent gain differences in FF filter 215 and FB filter 230, the error is scaled differently for each filter. This is represented in FIG. 2 by the use of individual adjustment signals 236 and 237 for FF filter 215 and FB filter 235, respectively. However, it should be noted that the inventive concept is not so limited and one adjustment signal could be provided to both filters.

In accordance with the principles of the invention, as adaptive filter is coupled to at least one error scaler (also referred to herein as a controller). The error scaler may be a part of the adaptive filter or external to the adaptive filter. In the context of the example illustrated by DFE 200, there are two error scalers 250 and 255, but the invention is not so limited. For example, there may be one error scaler that processes tap values from more than one adaptive filter, e.g., FF filter 215 and FB filter 230. For this example, error scalers 250 and 255 are similar in operation other than for the tap values that they process. As such, error scaler 250 is used to further illustrate the principles of the invention.

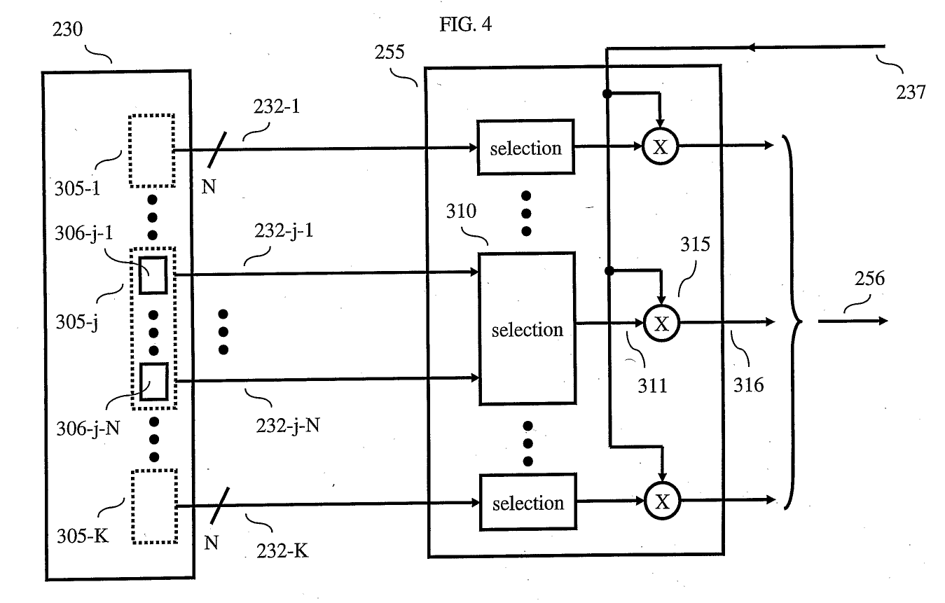

Turning now to FIG. 4, the relevant portion of DFE 200 is shown. FB filter 230 comprises a number of taps, T, (305). The number of taps, 305, are divided into K groups, each group having N taps, i.e., T=((K)(N)), where K>0 and N>0. This is illustrated in FIG. 4 by tap groups 305-1 through 305-K. A tap group is further illustrated in FIG. 4 by tap group 305-j, which comprises N taps as represented by taps 306-j-1 through 306-j-N, where 0<j≦K. It should be noted that although this example shows each tap group having the same number of taps, N, the invention is not so limited and the number of taps in each tap group may vary. As shown in FIG. 4, tap values for each tap group are coupled to selector 255. For example, signal 232-1 conveys the N tap values of tap group 305-1; signal 232-j conveys the N tap values of tap group 305-j (as represented by signals 231-j-1 through 232-j-N); and signal 232-K conveys the N tap values of tap group 305-K.

In accordance with the principles of the invention, each group of taps within an adaptive filter receives an error term to be used in their tap update process that has been scaled specifically for that group as a function of tap magnitude. One illustrative way of doing this is shown in FIG. 4. Selector 255 comprises a number of selection elements, where each selection element selects an error term, or scaler, which further adjusts the error from calculator 235. This further adjusted error is than provided to FB filter 230 for use in its tap update process. This is illustrated by selection element 310 of selector 255. Selection element 310 processes the N tap values of tap group 305-j and provides an error term, via signal 311, to multiplier 315. The latter multiplies the error from calculator 235 by the error term (conveyed via signal 237) to provide the above-mentioned further adjusted error back to FB filter 230, via signal 316 (which is a part of signal 256 of FIG. 3). Thus, and in accordance with the principles of the invention, the amount of error to be used in the tap update process for FB filter 230 has been specifically scaled for each tap group of FB filter 230. It should be noted that the method by which selector 255 examines the taps of a tap group can vary. For example, selector 255 can examine the taps in parallel (as illustrated in FIG. 4), or selector 255 can examine the taps in a serially, e.g., the tap values are scanned out serially for processing by selector 255. If serially, the group boundaries are assumed to be predetermined and their locations within the resulting serial stream of tap values known to selector 255. However, it should be noted that in the context of the invention, the group boundaries may also be programmable.

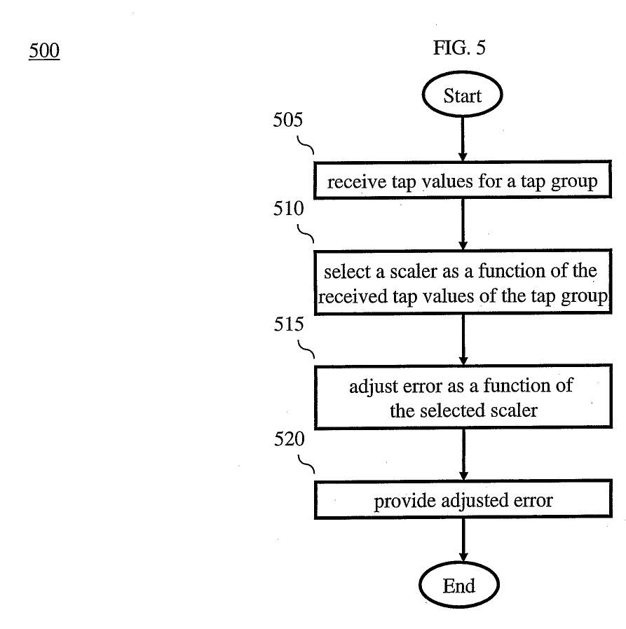

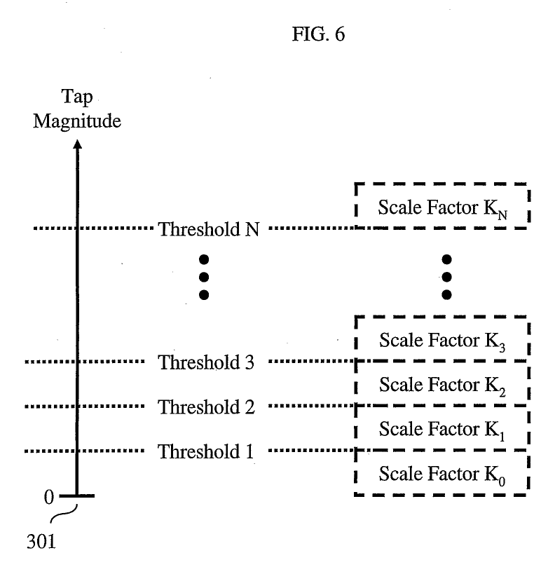

Turning now to FIG. 5, an illustrative flow chart for use in a selection element (e.g., selection element 310 of FIG. 4) is shown. In step 505, the selection element receives N tap values for a particular tap group. In step 510, selection element 510 selects a scaler, or scale factor (also referred to herein as a stepsize), as a function of the received N tap values of the tap group. An illustration of a selection function is shown in FIG. 6. It should be noted that the inventive concept is no so limited and other selection functions may be used. The selection process illustrated in FIG. 6 selects a scale factor as a function of the largest tap magnitude in the tap group. Axis 301 illustrates values of increasing tap magnitude. Selection element 510 determines the largest tap magnitude for tap group 305-j of FIG. 4 and selects the appropriate scale factor. In particular, if the determined largest tap magnitude is less than “Threshold 1”, then scale factor K₀ is selected; if the determined largest tap magnitude is less than “Threshold 2”, but greater than, or equal to, “Threshold 1”, then scale factor K₁ is selected, etc. In step 515, the selected scale factor is then used to adjust the error (e.g., multiplier 315 of FIG. 4). Finally, in step 520, the adjusted error is provided to the adaptive filter for use therein in the tap update process. It should be noted that the above-described thresholds may be adjustable or programmable. Further, if there is only one tap in the group, the scale factor selection is based only on the magnitude of that one tap.

As described above, and in accordance with an embodiment of the invention, a receiver comprises an equalizer, the equalizer having groups of taps, each group comprising at least one tap having an associated tap value; and wherein the equalizer adjusts tap values in each group, wherein the tap values of at least one group are adjusted as a function of a stepsize, the value of which is selected as a function of tap values of the group.

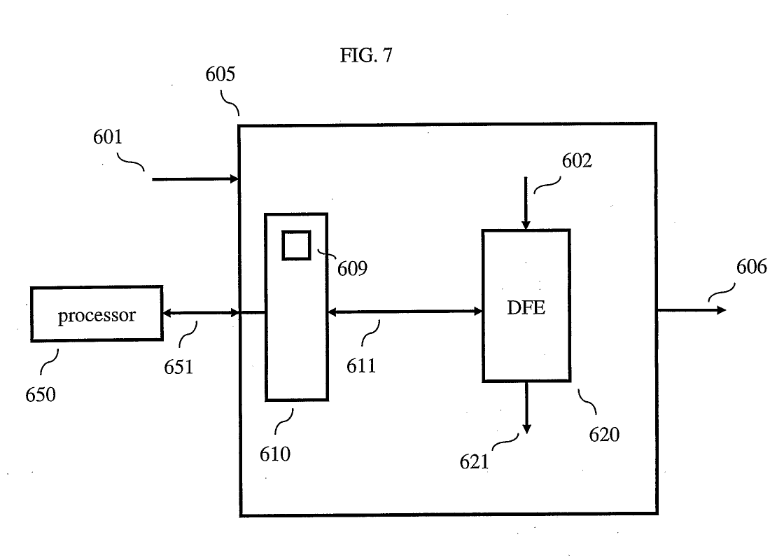

Another illustrative embodiment of the inventive concept is shown in FIG. 7. In this illustrative embodiment an integrated circuit (IC) 605 for use in a receiver (not shown) includes a DFE 620 and at least one register 610, which is coupled to bus 651. Illustratively, IC 605 is an integrated analog/digital television decoder. However, only those portions of IC 605 relevant to the inventive concept are shown. For example, analog-digital converters, other filters, decoders, etc., are not shown for simplicity. Bus 651 provides communication to, and from, other components of the receiver as represented by processor 650. Register 610 is representative of one, or more, registers, of IC 605, where each register comprises one, or more, bits as represented by bit 609. The registers, or portions thereof, of IC 605 may be read-only, write-only or read/write. In accordance with the principles of the invention, DFE 620 includes the above-described coefficient adjustment, or operating mode, and at least one bit, e.g., bit 609 of register 610, is a programmable bit that can be set by, e.g., processor 650, for enabling or disabling this tap value adjustment operating mode. In the context of FIG. 7, IC 605 receives an IF signal 601 for processing via an input pin, or lead, of IC 605. A related signal, 602, is applied to DFE 620 for filtering. The tap values of DFE 620 are further adjusted as described above (e.g., see FIGS. 4, 5 and 6). DFE 620 provides signal 621, which is representative of a filtered signal, e.g., the above-described signal 221. Although not shown in FIG. 7, signal 621 may be provided to circuitry external to IC 605 and/or be accessible via register 610. DFE 620 is coupled to register 610 via internal bus 611, which is representative of other signal paths and/or components of IC 605 for interfacing DFE 620 to register 610. IC 605 provides one, or more, recovered signals, e.g., a composite video signal, as represented by signal 606. It should be noted that other variations of IC 605 are possible in accordance with the principles of the invention, e.g., external control of the tap adjustment operating mode, e.g., via bit 610, is not required and IC 605 may simply always perform the above-described tap adjustment.

The present invention can be realized in hardware, software, or a combination of hardware and software. Aspects of the present invention also can be embedded in a computer program product, which comprises all the features enabling the implementation of the methods described herein, and which when loaded in a computer system is able to carry out these methods. Computer program or application in the present context means any expression, in any language, code or notation, of a set of instructions intended to cause a system having an information processing capability to perform a particular function either directly or after either or both of the following: a) conversion to another language, code or notation; b) reproduction in a different material form.

In view of the above, the foregoing merely illustrates the principles of the invention and it will thus be appreciated that those skilled in the art will be able to devise numerous alternative arrangements which, although not explicitly described herein, embody the principles of the invention and are within its spirit and scope. For example, although illustrated in the context of separate functional elements, these functional elements may be embodied on one or more integrated circuits (ICs). Similarly, although shown as separate elements, any or all of the elements of may be implemented in a stored-program-controlled processor, e.g., a digital signal processor, which executes associated software, e.g., corresponding to one or more of the steps shown in, e.g., FIG. 5, etc. Further, although shown as elements bundled within TV set 10, the elements therein may be distributed in different units in any combination thereof. For example, receiver 15 of FIG. 2 may be a part of a device, or box, such as a set-top box that is physically separate from the device, or box, incorporating display 20, etc. Also, it should be noted that although described in the context of terrestrial broadcast, the principles of the invention are applicable to any type of communications system where filtering is required, such as, but not limited to, satellite, cable, wireless, etc. It is therefore to be understood that numerous modifications may be made to the illustrative embodiments and that other arrangements may be devised without departing from the spirit and scope of the present invention as defined by the appended claims.

1. A receiver comprising:
an adaptive filter having groups of taps, each group comprising at least one tap having an associated tap value; and
a controller for selecting a scaling factor for at least one group of taps as a function of tap values of the group and for adjusting an error value as a function of the selected scaling factor;
wherein the adaptive filter adapts tap values of the at least one group of taps as a function of the adjusted error value.

2. The receiver of claim 1, wherein the adaptive filter is a part of an equalizer.

3. The receiver of claim 1, wherein the controller multiples the error value by the selected scaling factor to provide the adjusted error value.

4. The receiver of claim 1, wherein the controller determines a maximum tap value for the at least one group of taps and selects the scale factor as a function of the determined maximum tap value.

5. The receiver of claim 4, wherein the controller selects the scale factor by comparing the determined maximum tap value to a plurality of thresholds, each threshold associated with a particular scale factor.

6. A receiver comprising:
an equalizer having groups of taps, each group comprising at least one tap having an associated tap value; and
wherein the equalizer adjusts tap values in each group, wherein the tap values of at least one group are adjusted as a function of a stepsize, the value of which is selected as a function of tap values of the group.

7. The receiver of claim 6, further comprising:
a selector for provided the selected stepsize, wherein the selector determines a maximum tap value for the at least one group and selects the stepsize as a function of the determined maximum tap value.

8. The receiver of claim 7, wherein the selector is a part of the equalizer.

9. The receiver of claim 7, wherein the selector multiples an error value by the selected stepsize to provide an adjusted error value, which is used by the equalizer for adjusting the tap values of the at least one group.

10. The receiver of claim 7, wherein the selector selects the stepsize by comparing the determined maximum tap value to a plurality of thresholds, each threshold associated with a particular stepsize.

11. A method for use in a receiver, the method comprising:
adaptively filtering a signal with an adaptive filter having a number of taps, wherein the number of taps comprises a plurality of tap groups, each tap group having at least one tap;
determining an error value as a function of the filtered signal;
adjusting the error value as a function of tap values of at least one of the tap groups to provide an adjusted error value; and
adapting the taps of the at least one of the tap groups as a function of the adjusted error value.

12. The method of claim 11, wherein the adjusting step includes:
selecting a scaling factor as a function of the tap values of the at least one of the tap groups; and
multiplying the error value by the selected scaling factor to provide the adjusted error value.

13. The method of claim 12, wherein the selecting step includes:
determining a maximum tap value for the tap group; and
selecting the scale factor as a function of the determined maximum tap value.

14. The method of claim 13, wherein the selecting the scale factor step includes:
comparing the determined maximum tap value to a plurality of thresholds, each threshold associated with a particular scale factor

15. A method for use in a receiver, the method comprising:
equalizing a signal with an equalizer to provide an equalized signal, the equalizer having a plurality of tap groups, each tap group having at least one tap;
determining an error value as a function of the equalized signal;
adjusting the error value to provide an adjusted error value; and
adapting tap values of at least one of the plurality of tap groups as a function of the adjusted error value.

16. The method of claim 15, wherein the adjusting step includes:
selecting a stepsize as a function of tap values of the at least one tap group; and
adjusting the error value as a function of the selected stepsize to provide the adjusted error signal.

17. The method of claim 16, wherein the adjusting the error value step includes:
multiplying the error value by the selected stepsize to provide the adjusted error signal.

18. The method of claim 16, wherein the selecting step includes:
determining a maximum tap value from the taps values of the at least one tap group; and
selecting the stepsize as a function of the determined maximum tap value.

19. The method of claim 18, wherein the selecting the stepsize step include:
comparing the determined maximum tap value to a plurality of thresholds, each threshold associated with a particular stepsize.
